(19) United States
(12) Patent Application Publication
(10) Pub. No.: US 2025/0277140 A1
(43) Pub. Date: Sep. 4, 2025

(54) TRANSPARENT ADHESIVE SHEET, RELEASE FILM-PROVIDED TRANSPARENT ADHESIVE SHEET, TRANSPARENT ADHESIVE SHEET FOR MEMBER CONSTITUTING FLEXIBLE IMAGE DISPLAY DEVICE, LAMINATE FOR IMAGE DISPLAY DEVICE, AND FLEXIBLE IMAGE DISPLAY DEVICE

(71) Applicant: MITSUBISHI CHEMICAL CORPORATION, Tokyo (JP)

(72) Inventor: Kohei HIROSE, Tokyo (JP)

(73) Assignee: MITSUBISHI CHEMICAL CORPORATION, Tokyo (JP)

(21) Appl. No.: 19/212,525

(22) Filed: May 19, 2025

Related U.S. Application Data
(63) Continuation of application No. PCT/JP2023/040578, filed on Nov. 10, 2023.

(30) Foreign Application Priority Data
Nov. 22, 2022 (JP) 2022-186460

(51) Int. Cl. C09J 7/30; C09J 133/10; H10K 59/80; H10K 102/00

(52) U.S. Cl. CPC C09J 7/30; C09J 133/10; H10K 59/8722; C09J 2301/408; C09J 2301/414; H10K 2102/311

(57) ABSTRACT

The disclosure relates to a transparent adhesive sheet formed of an adhesive agent composition (I), in which the adhesive agent composition (I) contains a precursor containing a (meth)acrylic polymer (A), a compound (B) having, in a molecule, a radically polymerizable functional group having a carbon-carbon double bond, and a structure which generates a radical, and a photopolymerization initiator (C) consisting of a compound other than compound (B), and a storage shear modulus (G′(−20° C.)) at −20° C. obtained by a dynamic viscoelasticity measurement in a shear mode at a frequency of 1 Hz, is 10 kPa or more and 1,000 kPa or less.

### TECHNICAL FIELD

The present invention relates to a transparent adhesive sheet, a release film-provided transparent adhesive sheet, a transparent adhesive sheet for a member constituting a flexible image display device, a laminate for an image display device, and a flexible image display device.

This application is a continuation application of International Application No. PCT/JP2023/040578, filed on Nov. 10, 2023, which claims the benefit of priority of the prior Japanese Patent Application No. 2022-186460, filed Nov. 22, 2022, the content of which is incorporated herein by reference.

### BACKGROUND ART

In recent years, an image display device including a curved portion using an organic light-emitting diode (OLED) or quantum dots (QD), a flexible image display device capable of folding or rolling up, and the like have been developed and widely commercially available.

In such a display device, a plurality of sheet members such as a cover lens, a circular polarizing plate, a contact film sensor, a color filter, and a light-emitting element are bonded to each other by a transparent adhesive sheet to form a laminated structure, and when focusing on a certain adhesive sheet, it can be considered as a laminate in which the members and adhesive sheets are laminated.

Regarding a flexible image display device capable of winding, Patent Document 1 discloses an adhesive for a repeated bendable device, an adhesive sheet, a bendable layered member, and a repeated bendable device, in which a product value of a creep compliance fluctuation value and a relaxation elastic modulus fluctuation value can be set within a suitable range.

Patent Document 2 discloses an adhesive which can be hot-melted and with which an adhesive layer having excellent holding power and adhesive force can be formed, where the adhesive contains a (meth)acrylic polymer having a weight-average molecular weight of 50,000 to 1,000,000 obtained by polymerizing a macromonomer having a number-average molecular weight of 500 or more and less than 6,000 and a monomer mixture containing a vinyl monomer.

### CITATION LIST

### Patent Documents

Patent Document 1: Japanese Unexamined Patent Application, First Publication No. 2019-123826
Patent Document 2: PCT International Publication No. WO 2015/080244

### SUMMARY OF INVENTION

### Technical Problem

However, in the adhesive sheets of the related art such as Patent Documents 1 and 2, the sensitivity when curing by active energy rays is insufficient, and thus it is difficult to perform high-efficiency curing.

An object of the present invention is to provide a transparent adhesive sheet having high sensitivity to active energy rays that can be cured with high efficiency; and a release film-provided transparent adhesive sheet, a transparent adhesive sheet for a member constituting a flexible image display device, a laminate for an image display device, and a flexible image display device, each of which uses the transparent adhesive sheet.

### Solution to Problem

One embodiment of the present invention includes the following aspects.

[1]A transparent adhesive sheet formed of an adhesive agent composition (I),
wherein the adhesive agent composition (I) contains a precursor containing (meth)acrylic polymer (A), a compound (B) having, in a molecule, a radically polymerizable functional group having a carbon-carbon double bond, and a structure which generates a radical, and a photopolymerization initiator (C) consisting of a compound other than compound (B), and
a storage shear modulus (G′(−20° C.)) at −20° C. obtained by a dynamic viscoelasticity measurement in a shear mode at a frequency of 1 Hz, is 10 kPa or more and 1,000 kPa or less.

[2] The transparent adhesive sheet according to [1],
wherein a ratio ((G′(−20° C.)/G′(60° C.)) of the storage shear modulus G′(−20° C.) at −20° C. to a storage shear modulus G′(60° C.) at 60° C. obtained by the dynamic viscoelasticity measurement in the shear mode at the frequency of 1 Hz, is 20 or less.

[3] The transparent adhesive sheet according to [1] or [2],
wherein a storage shear modulus (G′(30° C.)) at 30° C. obtained by the dynamic viscoelasticity measurement in the shear mode at the frequency of 1 Hz, is 100 kPa or less.

[4] The transparent adhesive sheet according to any one of [1] to [3],
wherein compound (B) is an ethylenically unsaturated group-containing benzophenone-based compound.

[5] The transparent adhesive sheet according to any one of [1] to [4],
wherein compound (B) has at least one structure selected from a benzophenone structure, a benzil structure, an o-benzoyl benzoic acid ester structure, a thioxanthone structure, a 3-ketocoumarin structure, a 2-ethyl anthraquinone structure, or a camphorquinone structure.

[6] The transparent adhesive sheet according to any one of [1] to [5],
wherein the photopolymerization initiator (C) includes a hydrogen abstraction-type photoinitiator (C1).

[7] The transparent adhesive sheet according to any one of [1] to [6],
wherein the photopolymerization initiator (C) includes a cleavage-type photoinitiator (C2).

[8] The transparent adhesive sheet according to any one of [1] to [7],
wherein the glass transition temperature (Tg) defined by the maximal value of Tan δ obtained by the dynamic viscoelasticity measurement in the shear mode at the frequency of 1 Hz, is −20° C. or lower.

[9] The transparent adhesive sheet according to any one of [1] to [8],
wherein the contained amount of compound (B) is 0.01 parts by mass or more and 10 parts by mass or less with respect to 100 parts by mass of the (meth)acrylic polymer (A).

[10] The transparent adhesive sheet according to any one of [1] to [9],
wherein the mass ratio (B/C) of the contained amount of compound (B) to the contained amount of the photopolymerization initiator (C) is 0.2 to 10.

[11] The transparent adhesive sheet according to any one of [1] to [10],
wherein the adhesive agent composition (I) contains a photocurable compound (D).

[12] The transparent adhesive sheet according to any one of [1] to [11],
wherein the contained amount of a monofunctional urethane (meth)acrylate in the adhesive agent composition (I) is 10% by mass or less.

[13] The transparent adhesive sheet according to any one of [1] to [12],
wherein the adhesive agent composition (I) contains a silane coupling agent (E).

[14] The transparent adhesive sheet according to any one of [1] to [13],
wherein the (meth)acrylic polymer (A) is a block copolymer or a graft copolymer having a segment including a constituent unit derived from an alkyl (meth)acrylate having an alkyl group having 9 or more and 30 or less carbon atoms.

[15] The transparent adhesive sheet according to any one of [1] to [14],
wherein, when the thickness of the transparent adhesive sheet is set to 0.7 to 1.0 mm, a restoration rate calculated from the following expression, expressed with the strain (γₘₐₓ) when a pressure of 2 kPa is applied for 600 seconds at a temperature of 60° C. and a strain (γₘᵢₙ) after 600 seconds from unloading the stress, is 75% or more,

$$restoration rate ( \% ) = [ ( {γ}_{m ax} - {γ}_{m i n} ) / {γ}_{ma x} ] \times 100 .$$

[16] The transparent adhesive sheet according to any one of [1] to [15],
wherein the gel fraction is 45% or more.

[17]A release film-provided transparent adhesive sheet, comprising:
the transparent adhesive sheet according to any one of [1] to [16]; and a release film laminated with the transparent adhesive sheet.

[18]A transparent adhesive sheet for a member constituting a flexible image display device, comprising:
the transparent adhesive sheet according to any one of [1] to [16].

[19]A laminate for an image display device, comprising:
two members constituting an image display device; and
the transparent adhesive sheet according to any one of [1] to [16],
wherein the two members are laminated through the transparent adhesive sheet, and
at least one of the members constituting the image display device has a step with a height difference of 2 μm or more on a contact surface with the transparent adhesive sheet.

[20]A flexible image display device, comprising:
the laminate for an image display device according to [19].

### Advantageous Effects of Invention

According to the present invention, it is possible to provide a transparent adhesive sheet having high sensitivity to active energy rays that can be cured with high efficiency; and to provide a release film-provided transparent adhesive sheet, a transparent adhesive sheet for a member constituting a flexible image display device, a laminate for an image display device, and a flexible image display device, each of which uses the transparent adhesive sheet.

### DESCRIPTION OF EMBODIMENTS

Definitions of the following terms apply throughout the specification and claims.

“Structure which generates a radical” means a structure capable of generating a radical which initiates a polymerization reaction under excitation with active energy rays. Hereinafter, “structure which generates a radical” will also be referred to as “radical-generating structure”.

“Active energy ray” means an energy ray capable of generating an active species by decomposing a compound which generates an active species. Examples of such an active energy ray include visible light, ultraviolet rays, infrared rays, X-rays, α-rays, β-rays, γ-rays, and electron beams; and ultraviolet rays or electron beams are preferable, and ultraviolet rays are particularly preferable.

“(Meth)acrylate” is a generic term for acrylate and methacrylate. The same applies to “(meth)acryloyl group”, “(meth)acrylic acid”, “(meth)acrylonitrile”, and “(meth)acrylamide”.

“(Meth)acrylic polymer” means a polymer having a constituent unit derived from a (meth)acrylic monomer. The (meth)acrylic polymer may further have constituent units derived from monomers other than (meth)acrylic monomers (for example, styrene and the like).

“(Meth)acrylic monomer” means a monomer having a (meth)acryloyl group.

“Vinyl monomer” means a compound having an ethylenically unsaturated bond (polymerizable carbon-carbon double bond).

“to” indicating a numerical range means that the numerical values described before and after “to” are included as the lower limit value and the upper limit value.

### [Transparent Adhesive Sheet]

An embodiment of the present invention relates to a transparent adhesive sheet.

The transparent adhesive sheet according to the embodiment is a transparent adhesive sheet formed of an adhesive agent composition (I).

The adhesive agent composition (I) contains a precursor containing a (meth)acrylic polymer (A), a compound (B) having, in a molecule, a radically polymerizable functional group having a carbon-carbon double bond, and a radical-generating structure (hereinafter, also simply referred to as “compound (B)”), and a photopolymerization initiator (C) consisting of a compound other than compound (B).

Since compound (B) contained in the adhesive agent composition (I) has a plurality of the radical-generating structures in one molecule by polymerization of compounds (B) through the reaction of the radically polymerizable functional group, it is considered that compound (B) can act as a crosslinking point by forming a crosslinked structure in the (meth)acrylic polymer (A) through radical generation and radical recombination, for example. In addition, compound (B) can also function as a polymerization initiator by the action of the radical-generating structure. Compound (B) alone has an insufficient function as the polymerization initiator or has a significantly low function as the polymerization initiator, but compound (B) can sufficiently function as the polymerization initiator by being used in combination with the photopolymerization initiator (C).

“Precursor” in the adhesive agent composition (I) may include a state in which compounds (B) are not polymerized and all of compounds (B) are included in an unreacted state, and a state in which some or all of compounds (B) are polymerized to increase a molecular weight. In addition, a partially polymerized state in which the (meth)acrylic polymer (A) is partially polymerized to have a high molecular weight can be included.

### ((Meth)Acrylic Polymer (a))

Examples of the above-described (meth)acrylic polymer include a homopolymer of alkyl (meth)acrylate and a copolymer obtained by polymerizing alkyl (meth)acrylate and a monomer component which is copolymerizable with the alkyl (meth)acrylate.

Among the above, it is preferable that the (meth)acrylic polymer (A) be a copolymer including two or more copolymerizable components, in which at least one of the copolymerizable components is an alkyl (meth)acrylate having 4 to 30 carbon atoms in an alkyl group. The (meth)acrylic polymer (A) may be a block copolymer or a graft copolymer having a segment including a constituent unit derived from an alkyl (meth)acrylate having an alkyl group having 9 to 30 carbon atoms.

More specifically, examples of the (meth)acrylic polymer (A) include a copolymer of monomer components including the alkyl (meth)acrylate having 4 to 30 carbon atoms in an alkyl group and any one or more monomers copolymerizable with the alkyl (meth)acrylate, the monomers selected from (a1) a carboxy group-containing monomer other than the alkyl (meth)acrylate, (a2) a hydroxyl group-containing monomer, (a3) a nitrogen-containing monomer, (a4) an epoxy group-containing monomer, (a5) a vinyl monomer, (a6) an alkyl (meth)acrylate monomer having 1 to 3 carbon atoms in an alkyl group, (a7) an alicyclic monomer, (a8) a macromonomer, and (a9) other copolymerizable monomers.

(1) Among the above-described copolymerizable monomers (a1) to (a9), the following copolymerizable monomer (a1), (a2), or (a3) is particularly preferable.

(2) In addition, it is particularly preferable that the monomer component used to obtain the (meth)acrylic polymer (A) not include the above-described copolymerizable monomer (a1), and include any of the copolymerizable monomer (a2) or (a3); when either of the copolymerizable monomer (a2) or (a3) is included, it is possible to achieve both anticorrosion properties, adhesiveness, and moisture-heat whitening resistance when an adherend contains a component having corrosiveness, such as metal;

(3) Among the copolymerizable monomers (a3), a copolymerizable monomer (a3) having a tertiary nitrogen atom is preferable from the viewpoint of sensitizing the action of a hydrogen abstraction reaction described later, and as a result, crosslinking can be efficiently formed.

(4) Among the above-described alkyl (meth)acrylates, an alkyl (meth)acrylate containing a tertiary carbon atom in the alkyl group is preferable; by using such an alkyl (meth)acrylate, the hydrogen abstraction reaction is likely to occur during light irradiation, and as a result, crosslinking is likely to be efficiently formed.

The above-described alkyl (meth)acrylate is a linear or branched alkyl (meth)acrylate in which the number of carbon atoms in the alkyl group is 4 to 30, and is represented by Formula (1).

CH₂═CH(R¹)—COO(R²) (1)

(in the formula, R¹ represents a hydrogen atom or a methyl group, and R² represents a linear or branched alkyl group having 4 to 30 carbon atoms)

Examples of the alkyl (meth)acrylate represented by Formula (1) include linear alkyl (meth)acrylates such as n-butyl (meth)acrylate, n-pentyl (meth)acrylate, n-hexyl (meth)acrylate, n-heptyl (meth)acrylate, n-octyl (meth)acrylate, n-nonyl (meth)acrylate, n-decyl (meth)acrylate, undecyl (meth)acrylate, lauryl (meth)acrylate, n-tridecyl (meth)acrylate, n-tetradecyl (meth)acrylate, cetyl (meth)acrylate, stearyl (meth)acrylate, icosyl (meth)acrylate, henicosyl (meth)acrylate, and behenyl (meth)acrylate; and branched alkyl (meth)acrylates such as sec-butyl (meth)acrylate, isobutyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, isostearyl (meth)acrylate, isoicosyl (meth)acrylate, butyloctyl (meth)acrylate, isomethyl (meth)acrylate, isocetyl (meth)acrylate, hexyldecyl (meth)acrylate, isostearyl (meth)acrylate, octyldecyl (meth)acrylate, octyldodecyl (meth)acrylate, and isobehenyl (meth)acrylate. These may be used alone or in combination of two or more kinds thereof.

Among the above, a linear alkyl (meth)acrylate is preferable from the viewpoint of obtaining flexibility. In addition, from the viewpoint of balancing adhesiveness and flexibility, an alkyl (meth)acrylate having, in an alkyl group, 4 to 20 carbon atoms, more preferably 5 to 18 carbon atoms, particularly preferably 6 to 16 carbon atoms, and most preferably 7 to 14 carbon atoms is preferable. For example, n-butyl (meth)acrylate, n-pentyl (meth)acrylate, n-hexyl (meth)acrylate, n-octyl (meth)acrylate, n-nonyl (meth)acrylate, decyl (meth)acrylate, or lauryl (meth)acrylate is preferable.

In addition, from the viewpoint that a hydrogen abstraction reaction described later is likely to occur during light irradiation, and as a result, a crosslinked reaction can be efficiently formed, a branched alkyl (meth)acrylate is preferably used, and among these, a branched alkyl (meth)acrylate having, in an alkyl group, 4 to 20 carbon atoms, more preferably 5 to 18 carbon atoms, particularly preferably 6 to 16 carbon atoms, and most preferably 7 to 14 carbon atoms is preferable. For example, sec-butyl (meth)acrylate, isobutyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, or isodecyl (meth)acrylate is preferable.

The contained amount of the constitutional unit derived from the above-described alkyl (meth)acrylate to all constitutional units (100% by mass) constituting the (meth)acrylic polymer (A) is preferably 5% by mass or more and 95% by mass or less, more preferably 10% by mass or more and 90% by mass or less, still more preferably 15% by mass or more and 85% by mass or less, and particularly preferably 20% by mass or more and 80% by mass or less. When the proportion of the constitutional unit derived from the alkyl (meth)acrylate is equal to or more than the above-described lower limit value, the flexibility tends to be excellent, and unevenness followability when the adherend has unevenness tends to be excellent. When the proportion of the constitutional unit derived from the alkyl (meth)acrylate is equal to or less than the above-described upper limit value, an effect of the copolymerizable monomer described later is easily obtained, and the adhesive agent composition tends to have excellent adhesive force and cohesive force.

The upper limit and upper limit of the contained amount of the constitutional unit derived from the above-described alkyl (meth)acrylate can be arbitrarily combined.

Examples of the carboxy group-containing monomer (a1) include (meth)acrylic acid, 2-(meth)acryloyloxyethyl hexahydrophthalic acid, 2-(meth)acryloyloxypropyl hexahydrophthalic acid, 2-(meth)acryloyloxyethyl phthalic acid, 2-(meth)acryloyloxypropyl phthalic acid, 2-(meth)acryloyloxyethyl maleic acid, 2-(meth)acryloyloxypropyl maleic acid, 2-(meth)acryloyloxyethyl succinic acid, 2-(meth)acryloyloxypropyl succinic acid, crotonic acid, fumaric acid, maleic acid, and itaconic acid. These may be used alone or in combination of two or more kinds thereof.

Examples of the hydroxyl group-containing monomer (a2) include hydroxyalkyl (meth)acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate; caprolactone-modified hydroxy (meth)acrylates such as caprolactone-modified 2-hydroxyethyl (meth)acrylate; oxyalkylene-modified (meth)acrylates such as diethylene glycol (meth)acrylate and polyethylene glycol (meth)acrylate; primary hydroxyl group-containing (meth)acrylates such as 2-acryloyloxyethyl-2-hydroxyethyl phthalate; secondary hydroxyl group-containing (meth)acrylates such as 2-hydroxypropyl (meth)acrylate, 2-hydroxybutyl (meth)acrylate, and 3-chloro-2-hydroxypropyl (meth)acrylate; tertiary hydroxyl group-containing (meth)acrylates such as 2,2-dimethyl 2-hydroxyethyl (meth)acrylate; and vinyl ethers such as 2-hydroxyethyl vinyl ether, diethylene glycol monovinyl ether, and 4-hydroxybutyl vinyl ether. These can be used alone or in combination of two or more kinds thereof.

The adhesive sheet can be improved in adhesive force and can suppress moisture-heat whitening by the hydroxyl group-containing monomer (a2).

Among the hydroxyl group-containing monomers (a2), a hydroxyl group-containing monomer having, in a hydroxyalkyl group, 1 to 10 carbon atoms, more preferably 1 to 6 carbon atoms, and particularly preferably 2 to 4 carbon atoms, is preferable. For example, 2-hydroxyethyl (meth)acrylate, 4-hydroxybutyl (meth)acrylate, 2-hydroxypropyl (meth)acrylate, 2-hydroxyethyl vinyl ether, diethylene glycol monovinyl ether, or 4-hydroxybutyl vinyl ether is preferable; and a primary hydroxyl group-containing (meth)acrylate, for example, 2-hydroxyethyl (meth)acrylate or 4-hydroxybutyl (meth)acrylate is particularly preferable.

From the viewpoint of imparting adhesive force and moisture-heat whitening resistance, the contained amount of the constitutional unit derived from the hydroxyl group-containing monomer (a2) in the (meth)acrylic polymer (A) is preferably 3% to 30% by mass, more preferably 5% to 25% by mass, and particularly preferably 7% to 20% by mass with respect to all constitutional units of the (meth)acrylic polymer (A).

Examples of the nitrogen-containing monomer (a3) include an amino group-containing monomer, an amide group-containing monomer, an isocyanate group-containing monomer, and (meth)acrylonitrile. The adhesive sheet can be improved in cohesive force and can suppress moisture-heat whitening by the nitrogen-containing monomer (a3). These may be used alone or in combination of two or more kinds thereof. In addition, the nitrogen-containing monomer (a3) promotes a hydrogen abstraction reaction described later.

Examples of the above-described amino group-containing monomer include primary amino group-containing (meth)acrylates such as aminomethyl (meth)acrylate and aminoethyl (meth)acrylate; secondary amino group-containing (meth)acrylates such as t-butylaminoethyl (meth)acrylate and t-butylaminopropyl (meth)acrylate; tertiary amino group-containing (meth)acrylates such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropyl acrylamide; and monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, (meth)acryloylmorpholine, N-vinylacetamides, and N-vinylcaprolactam.

Examples of the above-described amide group-containing monomer include (meth)acrylamide; N-alkyl (meth)acrylamides such as N-methyl (meth)acrylamide, N-ethyl (meth)acrylamide, N-propyl (meth)acrylamide, N-n-butyl (meth)acrylamide, diacetone (meth)acrylamide, and N,N′-methylene bis(meth)acrylamide; N,N-dialkyl (meth)acrylamides such as N,N-dimethyl (meth)acrylamide, N,N-diethyl (meth)acrylamide, N,N-dipropyl (meth)acrylamide, N,N-ethyl methyl acrylamide, and N,N-diallyl (meth)acrylamide; hydroxyalkyl (meth)acrylamides such as N-hydroxymethyl (meth)acrylamide and N-hydroxyethyl (meth)acrylamide; alkoxyalkyl (meth)acrylamides such as N-methoxymethyl (meth)acrylamide and N-(n-butoxymethyl) (meth)acrylamide; and maleimide or a derivative thereof.

Examples of the above-described isocyanate group-containing monomer include 2-(meth)acryloyloxyethyl isocyanate and an alkylene oxide adduct thereof. The isocyanate group may be protected with a blocking agent such as methyl ethyl ketone oxime, 3,5-dimethylpyrazole, 1,2,4-triazole, and diethyl malonate.

Among the above, from the viewpoint of having a sensitizing action of a hydrogen abstraction reaction described later and thus being capable of efficiently forming crosslinking, a monomer having a tertiary nitrogen atom is preferable; and for example, a tertiary amino group-containing (meth)acrylate, N,N-dialkyl (meth)acrylamide, N-vinylpyrrolidone, or acryloylmorpholine is particularly preferable.

From the viewpoint of imparting adhesive force and moisture-heat whitening resistance, the contained amount of the constitutional unit derived from the nitrogen-containing monomer (a3) in the (meth)acrylic polymer (A) is preferably 0.1% to 15% by mass, more preferably 0.5% to 13% by mass, particularly preferably 1% to 10% by mass, and most preferably 2% to 7% by mass with respect to all constitutional units of the (meth)acrylic polymer (A).

Examples of the epoxy group-containing monomer (a4) include glycidyl (meth)acrylate, methylglycidyl (meth)acrylate, 3,4-epoxycyclohexylmethyl (meth)acrylate, and 4-hydroxybutyl (meth)acrylate glycidyl ether. These may be used alone or in combination of two or more kinds thereof.

Examples of the vinyl monomer (a5) include a compound having a vinyl group in the molecule. Examples of such a compound include vinyl ester monomers such as vinyl acetate, vinyl propionate, vinyl laurate, and vinyl stearate; and aromatic vinyl monomers such as styrene, chlorostyrene, chloromethylstyrene, α-methylstyrene, and other substituted styrenes. These may be used alone or in combination of two or more kinds thereof.

These can be used alone or in combination of two or more kinds thereof.

Examples of the alkyl (meth)acrylate monomer (a6) having 1 to 3 carbon atoms in an alkyl group include methyl (meth)acrylate, ethyl (meth)acrylate, n-propyl (meth)acrylate, and i-propyl (meth)acrylate. These may be used alone or in combination of two or more kinds thereof.

From the viewpoint of imparting cohesive force to the adhesive sheet, the contained amount of the constitutional unit derived from the copolymerizable monomer (a6) in the (meth)acrylic polymer (A) is preferably 0.1% to 15% by mass, more preferably 0.5% to 13% by mass, particularly preferably 1% to 10% by mass, and most preferably 2% to 7% by mass with respect to all constitutional units of the (meth)acrylic polymer (A).

Examples of the alicyclic monomer (a7) include cyclohexyl (meth)acrylate, 3,3,5-trimethylcyclohexyl (meth)acrylate, isobornyl (meth)acrylate, dicyclopentanyl (meth)acrylate, dicyclopentenyloxyethyl (meth)acrylate, t-butylcyclohexyl (meth)acrylate, and adamantyl (meth)acrylate. These may be used alone or in combination of two or more kinds thereof.

From the viewpoint of imparting cohesive force to the adhesive sheet, the contained amount of the constitutional unit derived from the alicyclic monomer (a7) in the (meth)acrylic polymer (A) is preferably 0.1% to 15% by mass, more preferably 0.5% to 13% by mass, particularly preferably 1% to 10% by mass, and most preferably 2% to 7% by mass with respect to all constitutional units of the (meth)acrylic polymer (A).

The macromonomer (a8) is a monomer capable of easily increasing the number of carbon atoms in a side chain to, for example, 20 or more, when a (meth)acrylic (co)polymer is polymerized. By using the macromonomer (a8), a (meth)acrylic (co)polymer can be made into a graft copolymer having a segment including the constitutional unit derived from the macromonomer (a8).

Therefore, the characteristics of the main chain and the side chain of the graft copolymer can be changed depending on the selection of the macromonomer (a8) and the other monomers, and on the blending ratio thereof.

It is preferable that the macromonomer (a8) have a skeleton component composed of an acrylic polymer or a vinyl-based polymer. Examples of the skeleton component of the macromonomer include the above-described linear or branched alkyl (meth)acrylates having 4 to 30 carbon atoms in alkyl, and the above-described copolymerizable monomers (a5), (a6), and (a7).

Among the above, it is preferable to use an alkyl (meth)acrylate having 1 to 8 carbon atoms in an alkyl group, an alicyclic monomer, or an aromatic monomer such as styrene, from the viewpoint that an adhesive sheet having excellent cohesive force can be obtained.

On the other hand, it is preferable to use an alkyl (meth)acrylate having 9 to 30 carbon atoms, from the viewpoint that an adhesive sheet having excellent flexibility can be obtained.

These can be used alone or in combination of two or more kinds thereof.

The macromonomer has a radically polymerizable functional group or a functional group such as a hydroxyl group, an isocyanate group, an epoxy group, a carboxy group, an amino group, an amide group, and a thiol group. The macromonomer preferably has a radically polymerizable functional group which can be copolymerized with other monomers. One or two or more kinds of the radically polymerizable functional groups may be contained, and among these, one kind of the radically polymerizable functional group is particularly preferable. Even when the macromonomer has a functional group, the macromonomer may contain one or two or more functional groups, and among these, it is particularly preferable that the macromonomer contain one functional group.

In addition, the macromonomer may contain either one of the radically polymerizable functional group or the functional group, or may contain both.

The weight-average molecular weight (Mw) of the macromonomer (a8) is preferably 1,000 or more and 40,000 or less, more preferably 1,500 or more and 20,000 or less, and still more preferably 2,000 or more and 15,000 or less.

As the macromonomer, a commercially available product (for example, a macromonomer manufactured by TOAGOSEI CO., LTD.) can be appropriately used.

The contained amount of the constitutional unit derived from the macromonomer (a8) in the (meth)acrylic polymer (A) is preferably 1% by mass or more and 30% by mass or less, more preferably 3% by mass or more and 20% by mass or less, and still more preferably 5% by mass or more and 15% by mass or less with respect to all constitutional units of the (meth)acrylic polymer (A). When the above-described contained amount is equal to or more than the above-described lower limit value, the force of phase separation between the segment including the constitutional unit derived from the macromonomer (a8) and a segment consisting of other constitutional units is increased, and thus shape retention of the adhesive sheet in a non-bonded state tends to be more excellent. When the above-described contained amount is equal to or less than the above-described upper limit value, the phase-separated structure tends to be easily destroyed during bonding, and thus unevenness followability tends to be more excellent. The lower limit and upper limit of the above-described contained amount can be arbitrarily combined.

Examples of the other copolymerizable monomer (a9) include (meth)acrylates having an alkoxyalkylene glycol skeleton, such as methoxydiethylene glycol (meth)acrylate, methoxypolyethylene glycol (meth)acrylate, butoxypolyethylene glycol (meth)acrylate, methoxypolypropylene glycol (meth)acrylate, butoxypolypropylene glycol (meth)acrylate, methoxypolytetramethylene glycol (meth)acrylate, butoxypolytetramethylene glycol (meth)acrylate, methoxypolyoxyethylene polyoxypropylene glycol (meth)acrylate, and butoxypolyoxyethylene polyoxypropylene glycol (meth)acrylate; aromatic (meth)acrylates having a benzophenone structure, such as phenyl (meth)acrylate, benzyl (meth)acrylate, phenoxyethyl (meth)acrylate, phenyldiethylene glycol (meth)acrylate, phenoxypolyethylene glycol (meth)acrylate, phenoxypolyethylene glycol-polypropylene glycol-(meth)acrylate, and nonylphenol ethylene oxide adduct (meth)acrylate; (meth)acrylates having a benzophenone structure, such as 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloxyethoxybenzophenone, 4-methacryloyloxy-4′-methoxybenzophenone, 4-methacryloxyethoxy-4′-methoxybenzophenone, 4-methacryloyloxy-4′-bromobenzophenone, 4-methacryloxyethoxy-4′-bromobenzophenone, and a mixture thereof, and heterocycle-containing (meth)acrylates such as tetrahydrofurfuryl (meth)acrylate.

In addition, a photocurable compound (D) having two or more functional groups, which will be described later, can also be used as the copolymerizable monomer. These can be used alone or in combination of two or more kinds thereof.

The weight-average molecular weight (Mw) of the (meth)acrylic polymer (A) is preferably 50,000 or more and 2,000,000 or less, more preferably 100,000 or more and 1,500,000 or less, and still more preferably 300,000 or more and 1,000,000 or less. When the weight-average molecular weight of the (meth)acrylic polymer (A) is equal to or more than the above-described lower limit value, durability of the transparent adhesive sheet after bonding tends to be favorable. When the weight-average molecular weight of the (meth)acrylic polymer (A) is equal to or less than the above-described upper limit value, moldability during manufacturing of the transparent adhesive sheet tends to be improved. The lower limit and the upper limit of the weight-average molecular weight of the (meth)acrylic polymer (A) can be arbitrarily combined.

In the present invention, the weight-average molecular weight (Mw) can be determined, for example, as follows.

### (Measurement Method of Weight Average Molecular Weight)

A 0.27% by mass tetrahydrofuran solution of the (meth)acrylic polymer is used as a measurement sample, and the weight-average molecular weight (Mw) in terms of standard polystyrene can be determined under the following conditions.
GPC device: “HLC-8320” manufactured by Tosoh Corporation
Column: two columns “TSKgel Super HZM-H” (6.0 mmID×15 cmL) manufactured by TOSOH Corporation are connected in series and used; as a guard column, “TSK guard column Super HZ-H” (4.6 mmID×3.5 cmL) manufactured by Tosoh Corporation is used.
Injection volume: 10 μL
Eluent: tetrahydrofuran (stabilizer: BHT)
Flow rate: 0.5 mL/min
Column temperature: 40° C.

The melt viscosity of the (meth)acrylic polymer (A) at 130° C. is preferably 20 Pa·s or more and 800 Pa·s or less, more preferably 20 Pa·s or more and 600 Pa·s or less, still more preferably 50 Pa·s or more and 600 Pa·s or less, and particularly preferably 100 Pa·s or more and 500 Pa·s or less. When the melt viscosity of the (meth)acrylic polymer (A) at 130° C. is within the above-described range, it is possible to perform coating by a hot melt method in which the resin composition (I) is heated and applied as it is. The lower limit and the upper limit of the melt viscosity of the (meth)acrylic polymer (A) at 130° C. can be arbitrarily combined.

The melt viscosity can be measured, for example, using a viscoelasticity measuring apparatus Rheosol-G5000 manufactured by UBM.

From the viewpoint of obtaining a transparent adhesive sheet having excellent flexibility, the glass transition temperature (Tg) of the (meth)acrylic polymer (A) is preferably −10° C. or lower, more preferably −20° C. or lower, and still more preferably −30° C. or lower. On the other hand, the lower limit of the glass transition temperature (Tg) of the (meth)acrylic polymer (A) is normally −80° C.

In the present invention, the glass transition temperature (Tg) is determined by reading a temperature at which a loss tangent (tan δ) is maximized when the dynamic viscoelasticity is measured in a shear mode at a frequency of 1 Hz, using a viscoelasticity measuring apparatus.

For example, the (meth)acrylic polymer is molded into a cylindrical body having a diameter of 8 mm (height: 1.0 mm), and a loss tangent (tan δ) of the molded body can be measured under the following measurement conditions using a viscoelasticity measuring apparatus (“DHR 2” manufactured by TA Instruments).

### (Measurement Conditions)

Measurement jig: Φ8 mm parallel plate
Strain: 0.1%
Frequency: 1 Hz
Measurement temperature: −60° C. to 100° C.
Temperature rising rate: 5° C./min

The (meth)acrylic polymer (A) preferably has a specific dielectric constant of 3.5 or less. When the specific dielectric constant is 3.5 or less, it is possible to reduce the thickness of the adhesive layer when the transparent adhesive sheet is mounted on a touch panel, and reactivity of the touch panel is favorable.

The production method of the (meth)acrylic polymer (A) is not particularly limited. For example, when the macromonomer (a8) has a radically polymerizable functional group, a method of polymerizing a monomer mixture containing the macromonomer (a8) and the alkyl (meth)acrylate having 4 to 30 carbon atoms in an alkyl group can be used. The monomer mixture may further contain the copolymerizable monomers (a1) to (a7), and (a9).

As the polymerization method, a known polymerization method such as a solution polymerization method, a suspension polymerization method, and an emulsion polymerization method can be used. In order to be used as the transparent adhesive sheet, a solution polymerization method is preferable.

When the macromonomer (a8) has a functional group having an addition reactivity and at least some of the copolymerizable monomers (a1) to (a7), and (a9) have a functional group capable of reacting with the functional group of the macromonomer (a8), a method of reacting (addition-reacting) the (meth)acrylic polymer (A) with the macromonomer (a8) can be used.

### (Compound (B))

Compound (B) has, in a molecule, a radically polymerizable functional group having a carbon-carbon double bond and a radical-generating structure. Compound (B) can be polymerized with compound (B) itself, and a crosslinked structure can be formed with the molecule of the (meth)acrylic polymer (A).

Examples of the “radically polymerizable functional group having a carbon-carbon double bond” include a functional group (ethylenically unsaturated group) having an unsaturated double bond, such as a (meth)acryloyl group and a vinyl group.

The radically polymerizable functional group included in compound (B) may be one or two or more, but is preferably one.

As the radical-generating structure, a structure which generates a radical by causing a hydrogen abstraction reaction when being excited by irradiation with active energy rays is preferable because a crosslinked structure is easily formed with the molecule of the (meth)acrylic polymer (A). Examples thereof include a benzophenone structure, a benzil structure, an o-benzoyl benzoic acid ester structure, a thioxanthone structure, a 3-ketocoumarin structure, a 2-ethyl anthraquinone structure, and a camphorquinone structure.

The radical-generating structure included in compound (B) may be one or two or more, but is preferably one.

Examples of compound (B) include compounds having an ethylenically unsaturated group such as a (meth)acryloyl group, and one or more selected from a benzophenone structure, a benzil structure, an o-benzoyl benzoic acid ester structure, a thioxanthone structure, a 3-ketocoumarin structure, a 2-ethyl anthraquinone structure, or a camphorquinone structure. Among the above, as compound (B), an ethylenically unsaturated group-containing benzophenone-based compound, specifically, a compound having a (meth)acryloyl group and a benzophenone structure is preferable.

Examples of compound (B) having a (meth)acryloyl group and a benzophenone structure include 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloxyethoxybenzophenone, 4-methacryloyloxy-4′-methoxybenzophenone, 4-methacryloxyethoxy-4′-methoxybenzophenone, 4-methacryloyloxy-4′-bromobenzophenone, and 4-methacryloxyethoxy-4′-bromobenzophenone.

Compound (B) may be used alone or in combination of two or more thereof.

In the present invention, from the viewpoint that the adhesive agent composition (I) can be sufficiently cured with a small amount of irradiation with active energy rays, the contained amount of compound (B) in the adhesive agent composition (I) is preferably 0.01 parts by mass or more and 10 parts by mass or less, particularly preferably 0.2 parts by mass or more and 5 parts by mass or less, and further preferably 0.5 parts by mass or more and 2 parts by mass or less with respect to 100 parts by mass of the (meth)acrylic polymer (A).

### (Photopolymerization Initiator (C))

The photopolymerization initiator (C) is a photopolymerization initiator consisting of a compound other than compound (B).

As the photopolymerization initiator (C), a compound which generates an active radical species by irradiation with light such as ultraviolet rays and visible rays, more specifically, with light having a wavelength of 200 nm to 780 nm can be used; and examples thereof include a hydrogen abstraction-type photoinitiator (C1) and a cleavage-type photoinitiator (C2). Among the above, the cleavage-type photoinitiator decomposes into another compound when generating a radical by light irradiation, and does not have a function as an initiator once it is excited. Therefore, the active species do not remain in the adhesive after the crosslinking reaction is completed, and there is no possibility of causing unexpected light deterioration or the like in the adhesive, which is preferable.

On the other hand, the hydrogen abstraction-type photoinitiator does not generate a decomposition product same as the cleavage-type photoinitiator with the radical generation reaction by irradiation with active energy rays such as ultraviolet rays, and thus it is difficult to become a volatile component after the reaction is completed, which is useful in that damage to an adherend can be reduced.

In the present invention, since a radical reaction point is generated in the (meth)acrylic polymer (A) to form a crosslinking point between the (meth)acrylic polymers (A), it is preferable that the photopolymerization initiator (C) include the hydrogen abstraction-type photoinitiator (C1).

Examples of the hydrogen abstraction-type photoinitiator (C1) include benzophenone, 4-methyl-benzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoyl formate, bis(2-phenyl-2-oxoacetic acid)oxybisethylene, 4-(1,3-acryloyl-1,4,7,10,13-pentaoxotridecyl)benzophenone, thioxanthone, 2-chlorothioxanthone, 3-methylthioxanthone, 2,4-dimethylthioxanthone, 2-methylanthraquinone, 2-ethylanthraquinone, 2-tert-butylanthraquinone, 2-aminoanthraquinone, and derivatives thereof.

Examples of the cleavage-type photoinitiator (C2) include 2,2-dimethoxy-1,2-diphenylethan-1-one, 1-hydroxycyclohexylphenylketone, 2-hydroxy-2-methyl-1-phenyl-propan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl}phenyl]-2-methyl-propan-1-one, oligo(2-hydroxy-2-methyl-1-(4-(1-methylvinyl)phenyl)propanone), methyl phenylglyoxylic acid, 2-benzyl-2-dimethylamino-1-(4-morpholinophenyl)butane-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, bis(2,6-trimethylbenzoyl) 2,4,4-trimethylpentylphosphine oxide, and derivatives thereof.

The photopolymerization initiator (C) may be used alone or in combination of two or more thereof.

In the present invention, from the viewpoint that the adhesive agent composition (I) can be sufficiently cured with a small amount of irradiation with active energy rays, the contained amount of the photopolymerization initiator (C) in the adhesive agent composition (I) is preferably 0.01 parts by mass or more and 10 parts by mass or less, particularly preferably 0.2 parts by mass or more and 5 parts by mass or less, and further preferably 0.5 parts by mass or more and 2 parts by mass or less with respect to 100 parts by mass of the (meth)acrylic polymer (A).

### (Photocurable Compound (D))

It is preferable that the adhesive agent composition (I) further contain a photocurable compound (D).

The photopolymerizable compound (D) has one or more radically polymerizable functional groups (here, excluding compound (B)). As the radically polymerizable functional group, a (meth)acryloyl group is preferable.

Examples of the photocurable compound (D) include a monofunctional (meth)acrylic monomer, a polyfunctional (meth)acrylic monomer, and a (meth)acrylic oligomer; and a polyfunctional (meth)acrylic monomer, a (meth)acrylic oligomer, or the like is preferable.

The monofunctional (meth)acrylic monomer has one (meth)acryloyl group.

Examples of the monofunctional (meth)acrylic monomer include monomers exemplified by the monomer forming the (meth)acrylic polymer (A).

The polyfunctional (meth)acrylic monomer has two or more (meth)acryloyl groups.

Examples of the polyfunctional (meth)acrylic monomer include 1,4-butanediol di(meth)acrylate, glycerin di(meth)acrylate, neopentyl glycol di(meth)acrylate, glycerin glycidyl ether di(meth)acrylate, 1,6-hexanediol di(meth)acrylate, 1,9-nonanediol di(meth)acrylate, tricyclodecane dimethacrylate, tricyclodecane dimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, trimethylolpropane trioxyethyl (meth)acrylate, F-caprolactone-modified tris(2-hydroxyethyl)isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol Tetra(meth)acrylate, dipentaerythritol hexa(meth)acrylate, polyethylene glycol di(meth)acrylate, polypropylene glycol di(meth)acrylate, polytetramethylene glycol di(meth)acrylate, (tris(acryloxyethyl)isocyanurate, dipentaerythritol hexa(meth)acrylate, dipentaerythritol penta(meth)acrylate, tripentaerythritol hexa(meth)acrylate, tripentaerythritol penta(meth)acrylate, neopentyl hydroxypivalate glycol di(meth)acrylate, di(meth)acrylate of F-caprolactone adduct of neopentyl hydroxypivalate, trimethylolpropane tri(meth)acrylate, trimethylolpropane polyethoxytri(meth)acrylate, and ditrimethylolpropane tetra(meth)acrylate.

Among the above, from the viewpoint of imparting appropriate toughness to the cured product, a polyfunctional (meth)acrylic monomer having an alkylene glycol skeleton, such as polyethylene glycol di(meth)acrylate, polypropylene glycol di(meth)acrylate, and polytetramethylene glycol di(meth)acrylate, is more preferable.

From the viewpoint of imparting appropriate flexibility to the cured product, the molecular weight of the polyfunctional (meth)acrylic monomer is preferably 200 or more, more preferably 300 or more, still more preferably 400 or more, and particularly preferably 500 or more. The upper limit of the molecular weight of the polyfunctional (meth)acrylic monomer is usually 3,000 or less, preferably 2,000 or less.

Examples of the (meth)acrylic oligomer include polyester (meth)acrylate, epoxy (meth)acrylate, urethane (meth)acrylate, and polyether (meth)acrylate.

Among the above, from the viewpoint of imparting appropriate toughness to the cured product, urethane (meth)acrylate-based oligomer is preferable.

However, from the viewpoint of curability, the contained amount of the monofunctional urethane (meth)acrylate in the adhesive agent composition (I) is preferably 10% by mass or less, more preferably 5% by mass or less, still more preferably 3% by mass or less, and particularly preferably 1% by mass or less with respect to the total mass of the adhesive agent composition (I). When the contained amount is too high, the curability tends to decrease.

When the transparent adhesive sheet according to the embodiment is cured, from the viewpoint that a cured product having high toughness is obtained, in other words, from the viewpoint that a cured product with appropriate flexibility is obtained, the molecular weight of the (meth)acrylic oligomer is preferably 3,000 or more, more preferably 5,000 or more, still more preferably 8,000 or more, and particularly preferably 10,000 or more. The upper limit of the molecular weight is usually 100,000 or less, preferably 50,000 or less.

The photocurable compound (D) may be used alone or in combination of two or more thereof.

### (Silane Coupling Agent (E))

It is preferable that the adhesive agent composition (I) further contain a silane coupling agent (E).

The silane coupling agent (E) is not particularly limited, and a silane coupling agent containing a glycidyl group or having a (meth)acryloyl group or a vinyl group is particularly preferable. When the silane coupling agent (E) is included, adhesiveness to the member sheet is improved when the transparent adhesive sheet is laminated on the member sheet, and a foaming phenomenon in a hot humid environment can be suppressed.

Examples thereof include a monomer-type epoxy group-containing silane coupling agent which is a silane compound, such as 3-glycidoxypropyltrimethoxysilane, 3-glycidoxypropyltriethoxysilane, 3-glycidoxypropylmethyldiethoxysilane, 3-glycidoxypropylmethyldimethoxysilane, and 2-(3,4-epoxycyclohexyl)ethyltrimethoxysilane; an oligomer-type epoxy group-containing silane coupling agent in which some of the silane compound is hydrolyzed and condensed or the silane compound is co-condensed with an alkyl group-containing silane compound, such as methyltriethoxysilane, ethyltriethoxysilane, methyltrimethoxysilane, and ethyltrimethoxysilane; a monomer-type mercapto group-containing silane coupling agent which is a silane compound, such as 3-mercaptopropyltrimethoxysilane, 3-mercaptopropyltriethoxysilane, γ-mercaptopropyldimethoxymethylsilane, and 3-mercaptopropylmethyldimethoxysilane; an oligomer-type mercapto group-containing silane coupling agent in which some of the silane compound is hydrolyzed and condensed or the silane compound is co-condensed with an alkyl group-containing silane compound, such as methyltriethoxysilane, ethyltriethoxysilane, methyltrimethoxysilane, and ethyltrimethoxysilane; a (meth)acryloyl group-containing silane coupling agent such as 3-acryloxypropyltrimethoxysilane, 3-methacryloxypropyltrimethoxysilane, 3-methacryloxypropylmethyldiethoxysilane, 3-methacryloxypropyltriethoxysilane, and 3-acryloxypropyltrimethoxysilane; an amino group-containing silane coupling agent such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, and N-phenyl-3-aminopropyltrimethoxysilane; an isocyanate group-containing silane coupling agent such as 3-isocyanatepropyltriethoxysilane; and a vinyl group-containing silane coupling agent such as vinyltrimethoxysilane and vinyltriethoxysilane.

The silane coupling agent (E) may be used alone or in combination of two or more thereof.

### (Other Components)

Various additives such as a viscosity-imparting resin, a plasticizer, an antioxidant, a light stabilizer, a metal inactivator, an anti-aging agent, a moisture absorbent, a polymerization inhibitor, an ultraviolet absorber, a rust inhibitor, inorganic particles, a sensitizer, and a pigment may be added to the adhesive agent composition (I) as necessary. It is preferable that the amount of these additives be typically set to not adversely affect the curing of the transparent adhesive sheet or to not adversely affect the physical characteristics of the transparent adhesive sheet.

### (Formulation of Adhesive Agent Composition (I))

The contained amount of the (meth)acrylic polymer (A) in the adhesive agent composition (I) is preferably 50% by mass or more, more preferably 75% by mass or more, and still more preferably 90% by mass or more with respect to the total mass of the adhesive agent composition (I). The contained amount of the (meth)acrylic polymer (A) is preferably 99.5% by mass or less, more preferably 99% by mass or less, and still more preferably 98% by mass or less with respect to the total mass of the adhesive agent composition (I). The lower limit and the upper limit of the above-described contained amount of the (meth)acrylic polymer (A) can be arbitrarily combined.

Since the adhesive agent composition (I) can be sufficiently cured with a small amount of irradiation with active energy rays, the contained amount of compound (B) in the adhesive agent composition (I) is preferably 0.01% by mass or more, more preferably 0.1% by mass or more, still more preferably 0.2% by mass or more, particularly preferably 0.3% by mass or more, and most preferably 0.5% by mass or more with respect to the total mass of the adhesive agent composition (I). From the viewpoint of suppressing a decrease in adhesive force due to excessive curing, the contained amount of compound (B) is preferably 10% by mass or less, more preferably 5% by mass or less, still more preferably 2% by mass or less, and particularly preferably 1.5% by mass or less with respect to the total mass of the adhesive agent composition (I). The lower limit and upper limit of the above-described contained amount of compound (B) can be arbitrarily combined.

Since the adhesive agent composition (I) can be sufficiently cured with a small amount of irradiation with active energy rays, the contained amount of the photopolymerization initiator (C) in the adhesive agent composition (I) is preferably 0.01% by mass or more, more preferably 0.1% by mass or more, still more preferably 0.2% by mass or more, and particularly preferably 0.3% by mass or more with respect to the total mass of the adhesive agent composition (I). From the viewpoint of suppressing a decrease in adhesive force due to excessive curing, the contained amount of the photopolymerization initiator (C) is preferably 10% by mass or less, more preferably 5% by mass or less, still more preferably 2% by mass or less, and particularly preferably 1.5% by mass or less with respect to the total mass of the adhesive agent composition (I). The lower limit and upper limit of the above-described contained amount of the photopolymerization initiator (C) can be arbitrarily combined.

Since the generated radicals efficiently generate the crosslinking point, the mass ratio (B/C) of the contained amount of compound (B) to the contained amount of the photopolymerization initiator (C) in the adhesive agent composition (I) is preferably 0.2 or more, more preferably 0.5 or more, and still more preferably 0.7 or more. From the viewpoint that the radical generation efficiency can be increased, the mass ratio (B/C) is preferably 10 or less, more preferably 5 or less, and still more preferably 2 or less. The above-described lower limit and upper limit of the above-described mass ratio (B/C) of the contained amounts can be arbitrarily combined.

Since the curing can be sufficiently advanced with a small amount of irradiation with active energy rays, the total contained amount of compound (B) and the photopolymerization initiator (C) is preferably 0.02 parts by mass or more, more preferably 0.2 parts by mass or more, still more preferably 0.3 parts by mass or more, and particularly preferably 0.5 parts by mass or more with respect to 100 parts by mass of the (meth)acrylic polymer (A). From the viewpoint of suppressing a decrease in adhesive force due to an excessive number of crosslinking points, the total contained amount of compound (B) and the photopolymerization initiator (C) is preferably 10 parts by mass or less, more preferably 5 parts by mass or less, still more preferably 3 parts by mass or less, and particularly preferably 2 parts by mass or less with respect to 100 parts by mass of the (meth)acrylic polymer (A). The above-described lower limit and upper limit of the above-described total contained amount of compound (B) and the photopolymerization initiator (C) can be arbitrarily combined.

From the viewpoint of easily imparting excellent durability when forming a laminate of the transparent adhesive sheet, the contained amount of the photocurable compound (D) in the adhesive agent composition (I) is preferably 0.1 parts by mass or more, more preferably 0.5 parts by mass or more, still more preferably 1.2 parts by mass or more, and particularly preferably 1.5 parts by mass or more with respect to 100 parts by mass of the (meth)acrylic polymer (A). On the other hand, from the viewpoint of ensuring the shape retention or the adhesiveness of the transparent adhesive sheet, the contained amount of the photocurable compound (D) is preferably 10 parts by mass or less, more preferably 5 parts by mass or less, still more preferably 3 parts by mass or less, and particularly preferably 2 parts by mass or less with respect to 100 parts by mass of the (meth)acrylic polymer (A). The lower limit and upper limit of the above-described contained amount of the photocurable compound (D) can be arbitrarily combined.

From the viewpoint of ensuring durability in a reliability test when incorporated into an image display device, the contained amount of the silane coupling agent (E) in the adhesive agent composition (I) is preferably 0.05 parts by mass or more, more preferably 0.1 parts by mass or more, and still more preferably 0.2 parts by mass or more with respect to 100 parts by mass of the (meth)acrylic polymer (A). From the viewpoint of suppressing a decrease in adhesive force due to the side reaction, the contained amount of the silane coupling agent (E) is preferably 1 part by mass or less, more preferably 0.7 parts by mass or less, and still more preferably 0.5 parts by mass or less with respect to 100 parts by mass of the (meth)acrylic polymer (A). The lower limit and upper limit of the above-described contained amount of the silane coupling agent (E) can be arbitrarily combined.

### (Physical Properties of Transparent Adhesive Sheet)

Hereinafter, physical properties of the transparent adhesive sheet according to an example of the embodiment will be described. Each physical property of the transparent adhesive sheet described below is a physical property of the transparent adhesive sheet formed of the adhesive agent composition (I), and is preferably a physical property of the transparent adhesive sheet after being cured by irradiation with ultraviolet rays so that the integrated light amount at a wavelength of 365 nm is any irradiation amount of, for example, 500 to 5,000 mJ/cm².

The transparent adhesive sheet according to one example of the embodiment satisfies the following requirement (1). In addition, it is preferable that the transparent adhesive sheet according to one example of the embodiment satisfy any one or both of the following requirement (2) and requirement (3).

(1) A storage shear modulus (G′(−20° C.)) at −20° C. obtained by a dynamic viscoelasticity measurement in a shear mode at a frequency of 1 Hz, is 10 kPa or more and 1,000 kPa or less.

(2) A ratio ((G′(−20° C.)/G′(60° C.)) of the storage shear modulus G′(−20° C.) at −20° C. to a storage shear modulus G′(60° C.) at 60° C. obtained by a dynamic viscoelasticity measurement in a shear mode at a frequency of 1 Hz, is 20 or less.

(3) A storage shear modulus (G′(30° C.)) at 30° C. obtained by a dynamic viscoelasticity measurement in a shear mode at a frequency of 1 Hz, is 100 kPa or less.

The transparent adhesive sheet satisfying requirement (1) is flexible even at a low temperature, and has excellent flexibility. For example, even when a folding operation is repeatedly performed at a low temperature of −20° C., cracks or breakage are less likely to occur in a member which is an adherend of the transparent adhesive sheet. From the viewpoint of shape retention of the transparent adhesive sheet in a non-bonded state and viewpoint of durability after bonding, G′(−20° C.) of requirement (1) is more preferably 30 kPa or more, still more preferably 50 kPa or more, and particularly preferably 100 kPa or more. On the other hand, from the viewpoint of flexibility of the transparent adhesive sheet in a low-temperature environment, G′(−20° C.) of requirement (1) is more preferably 500 kPa or less, still more preferably 300 kPa or less, particularly preferably 250 kPa or less, and most preferably 200 kPa or less. The above-described lower limit and upper limit of G′(−20° C.) of requirement (1) can be arbitrarily combined.

Examples of a method of adjusting G′(−20° C.) of requirement (1) in the transparent adhesive sheet to the above-described range include a method of adjusting the formulation or molecular weight of the (meth)acrylic polymer (A) and the kind or addition amount of the photocurable compound (D). However, the method is not limited to these methods.

The transparent adhesive sheet satisfying requirement (2) has an excellent balance between flexibility in a low-temperature environment and a high temperature adhesive force.

From the viewpoint of improving flexibility in a low-temperature environment, G′(−20° C.)/G′(60° C.) of requirement (2) is preferably 20 or less, more preferably 15 or less, and still more preferably 10 or less. From the viewpoint of improving the high temperature adhesive force, G′(−20° C.)/G′(60° C.) of requirement (2) is preferably 3 or more, more preferably 5 or more, and still more preferably 7 or more. The above-described lower limit and upper limit of G′(−20° C.)/G′(60° C.) of requirement (2) can be arbitrarily combined.

Examples of a method of adjusting G′(−20° C.)/G′(60° C.) of requirement (2) in the transparent adhesive sheet to the above-described range include a method of adjusting the formulation or molecular weight of the (meth)acrylic polymer (A) and the kind or addition amount of the photopolymerizable compound, and a method of adjusting the amount of irradiation with active energy rays. However, the method is not limited to these methods.

The adhesive sheet satisfying requirement (3) has excellent flexibility.

From the viewpoint of excellent flexibility, G′(30° C.) of requirement (3) is more preferably 80 kPa or less, still more preferably 60 kPa or less, and particularly preferably 50 kPa or less. Since the shape retention is exhibited, G′(30° C.) of requirement (3) is preferably 5 kPa or more, more preferably 10 kPa or more, and still more preferably 15 kPa or more. The above-described lower limit and upper limit of G′(30° C.) of requirement (3) can be arbitrarily combined.

Examples of a method of adjusting G′(30° C.) of requirement (3) in the transparent adhesive sheet to the above-described range include a method of adjusting the formulation or molecular weight of the (meth)acrylic polymer (A) and the kind or addition amount of the photocurable compound (D). However, the method is not limited to these methods.

In order to accurately measure the storage shear modulus G′, it is necessary to avoid fluctuations in measurement results due to influence of a measurement jig by insufficient thickness of the transparent adhesive sheet.

The storage shear modulus G′ in the requirements (1) to (3) is a value measured after adjusting the thickness in a range of 0.7 to 1.0 mm, and thus the storage shear modulus G′ can be accurately measured without being affected by a measurement jig.

The above-described “adjusting the thickness in a range of 0.7 to 1.0 mm” means that, when the thickness of the transparent adhesive sheet used as a measurement sample is not within this range, the thickness of the measurement sample is adjusted to within this range by stacking several sheets. The same applies to other tests when the thickness of the measurement sample is defined.

For example, the measurement of G′(−20° C.), G′(60° C.), and G′(30° C.) in the requirements (1) to (3) is performed as follows.

After repeatedly laminating the transparent adhesive sheet to adjust the thickness thereof to 0.7 to 1.0 mm, a circular sample having a diameter of 8 mm is punched out. A dynamic viscoelasticity measurement of the obtained sample is performed using a rheometer under the conditions of a measurement jig of 8 mm-diameter parallel plate, a frequency of 1 Hz, a measurement temperature of −50° C. to 150° C., and a temperature rising rate of 5° C./min, and a value of storage shear modulus (G′) at −20° C., 30° C., and 60° C. is read.

The transparent adhesive sheet according to one example of the embodiment preferably satisfies the following requirement (4).

(4) When the thickness is set to 0.7 to 1.0 mm, a strain (creep strain) by applying a pressure of 2 kPa at a temperature of 60° C. for 600 seconds is 3% or more and 1000% or less.

The transparent adhesive sheet satisfying requirement (4) is easily deformed at a high temperature and has excellent unevenness followability during bonding, and thus, tends to have excellent followability to a step even when the member constituting an image display device, as an adherend, has an uneven surface. In addition, the laminate sheet or the member constituting a flexible image display device has excellent followability when bent at a high temperature, and can suppress delamination or breakage of the member sheet or the flexible member.

From such a viewpoint, the creep strain of requirement (4) is more preferably 5% or more, still more preferably 6% or more, and particularly preferably 7% or more. On the other hand, from the viewpoint of shape retention of the transparent adhesive sheet at room temperature or lower, the creep strain of requirement (4) is more preferably 800% or less, still more preferably 500% or less, and particularly preferably 200% or less. The above-described lower limit and upper limit of the creep strain of requirement (4) can be arbitrarily combined.

For example, the measurement of the creep strain of requirement (4) is carried out as follows.

After repeatedly laminating the transparent adhesive sheet to adjust the thickness thereof to 0.7 to 1.0 mm (for example, 0.8 mm), a circular sample having a diameter of 8 mm is punched out. A strain (creep strain) (%) of the obtained sample after 600 seconds is measured using a rheometer under the conditions of a measurement jig of 8 mm-diameter parallel plate, a temperature of 60° C., and a pressure of 2 kPa.

Examples of a method of adjusting the creep strain of requirement (4) to the above-described range include a method of adjusting the formulation or molecular weight of the (meth)acrylic polymer (A) and the kind or addition amount of the photocurable compound (D), and a method of adjusting the amount of irradiation with active energy rays. However, the method is not limited to these methods.

The transparent adhesive sheet according to one example of the embodiment preferably satisfies the following requirement (5).

(5) In a retention force measurement in accordance with JIS-Z-0237 (ISO29863), a deviation amount after 30 minutes is 5 mm or less when the film is bonded to an SUS plate having an area of 20 mm×20 mm and a load of 500 gf is applied thereto in an atmosphere of 70° C.

The transparent adhesive sheet satisfying requirement (5) has high shape retention, does not allow the transparent adhesive sheet to protrude from between the release films during storage before bonding, and thus a transparent adhesive sheet having excellent storage stability and excellent durability can be obtained.

From such a viewpoint, the deviation amount of requirement (5) is preferably 3 mm or less, more preferably 2 mm or less, still more preferably 1 mm or less, particularly preferably 0.5 mm or less, and most preferably 0.2 mm or less. The lower limit of the deviation amount is usually 0 mm.

For example, the measurement of the holding power of requirement (5) is carried out as follows.

A polyester film for backing was attached to one surface of the transparent adhesive sheet, and the transparent adhesive sheet was cut into strips with a width of 20 mm and a length of 100 mm to obtain a test piece. One end portion of the above-described test piece was adhered to an SUS plate such that an adhesive area was 20 mm×20 mm. After curing for 15 minutes in an atmosphere of 70° C., a weight of 500 gf (4.9 N) was provided at the other end portion of the above-described test piece. The SUS plate was allowed to stand vertically such that the weight side was on the lower side, and after a load was applied to the test piece for 30 minutes, a distance (deviation amount) at which the test piece deviated was measured.

Examples of a method of adjusting the holding power of requirement (5) to the above-described range include a method of adjusting the formulation or molecular weight of the (meth)acrylic polymer (A) and the kind or addition amount of the photocurable compound (D). However, the method is not limited to these methods.

The transparent adhesive sheet according to one example of the embodiment preferably satisfies the following requirement (6).

(6) The glass transition temperature (Tg) defined by the maximal value of Tan δ obtained by a dynamic viscoelasticity measurement in a shear mode at a frequency of 1 Hz, is −20° C. or lower.

The transparent adhesive sheet satisfying requirement (6) has excellent flexibility.

From the viewpoint of obtaining excellent flexibility, Tg of requirement (6) is preferably −25° C. or lower, more preferably −30° C. or lower, and still more preferably −35° C. or lower. On the other hand, the lower limit thereof is usually −80° C.

Examples of a method of adjusting Tg of requirement (6) to the above-described range include a method of adjusting the formulation or molecular weight of the (meth)acrylic polymer (A) and the kind or addition amount of the photocurable compound, and a method of adjusting the amount of irradiation with active energy rays. However, the method is not limited to these methods.

The transparent adhesive sheet according to one example of the embodiment preferably satisfies the following requirement (7).

(7) When the thickness of the transparent adhesive sheet is set to 0.7 to 1.0 mm, a restoration rate calculated from the following expression, expressed with a strain (γₘₐₓ) when a pressure of 2 kPa is applied for 600 seconds at a temperature of 60° C. and the strain (γₘᵢₙ) after 600 seconds from unloading the stress, is 75% or more.

$$Restoration rate ( \% ) = [ ( {γ}_{m ax} - {γ}_{m i n} ) / {γ}_{m ax} ] \times 100$$

The transparent adhesive sheet satisfying requirement (7) has excellent restoring properties during bending.

From the viewpoint of obtaining a transparent adhesive sheet having excellent restoring properties during bending, the restoration rate of requirement (7) is preferably 80% or more, more preferably 90% or more, and still more preferably 95% or more. From the viewpoint of improving the adhesive force, the restoration rate of requirement (7) is preferably 99% or less, more preferably 98% or less, and still more preferably 97% or less. The above-described lower limit and upper limit of the restoration rate of requirement (7) can be arbitrarily combined.

For example, the measurement of the restoration rate of requirement (7) is carried out as follows.

After repeatedly laminating the transparent adhesive sheet to adjust the thickness thereof to 0.7 to 1.0 mm, a circular sample having a diameter of 8 mm is punched out. For the obtained sample, a strain (γₘₐₓ) after applying a pressure of 2 kPa at 60° C. for 600 seconds and a strain (γₘᵢₙ) after the stress is released and 600 seconds have elapsed are measured using a rheometer. The obtained values are substituted into the following expression to calculate the restoration rate.

$$Restoration rate ( \% ) = [ ( {γ}_{m ax} - {γ}_{m i n} ) / {γ}_{m ax} ] \times 100$$

Examples of a method of adjusting the restoration rate of requirement (7) to the above-described range include a method of adjusting the formulation or molecular weight of the (meth)acrylic polymer (A) and the kind or addition amount of the photopolymerizable compound, and a method of adjusting the amount of irradiation with active energy rays. However, the method is not limited to these methods.

The transparent adhesive sheet according to one example of the embodiment preferably satisfies the following requirement (8).

(8) The gel fraction of the transparent adhesive sheet is 45% or more.

The adhesive sheet satisfying requirement (8) has excellent active energy ray curability.

From the viewpoint of active energy ray curability, the gel fraction of requirement (8) is preferably 50% or more, more preferably 60% or more, still more preferably 70% or more, and particularly preferably 75% or more. On the other hand, from the viewpoint of obtaining the adhesive force, the gel fraction of requirement (8) is preferably 90% or less, more preferably 87% or less, and still more preferably 85% or less. The above-described lower limit and upper limit of the gel fraction of requirement (8) can be arbitrarily combined.

For example, the measurement of the gel fraction of requirement (8) is carried out as follows.

A pre-weighed transparent adhesive sheet is wrapped in an SUS wire mesh of 150 mesh, and immersed in ethyl acetate for 24 hours. Thereafter, the adhesive sheet is dried at 70° C. for 4.5 hours, the mass of the adhesive before and after the immersion in ethyl acetate is measured, and the difference between the masses is defined as the mass (mass after immersion) of the adhesive remaining in the wire mesh in an insoluble state. The percentage of the mass of the insoluble adhesive remaining in the wire mesh (mass after immersion) with respect to the mass of the adhesive before immersion in ethyl acetate (mass before immersion) is calculated as the gel fraction (%) in the fully cured state.

Examples of a method of adjusting the gel fraction of requirement (8) to the above-described range include a method of adjusting the formulation or molecular weight of the (meth)acrylic polymer (A) and the kind or addition amount of the photopolymerizable compound, and a method of adjusting the amount of irradiation with active energy rays.

However, the method is not limited to these methods.

The transparent adhesive sheet according to the embodiment may have a single-layer configuration or a multilayer configuration. When a multilayer configuration, each of the plurality of layers is formed of the adhesive agent composition containing the (meth)acrylic polymer (A).

From the viewpoint that handleability is favorable and excellent unevenness followability is easily obtained, the thickness of the transparent adhesive sheet according to the embodiment is preferably 5 μm or more, more preferably 10 μm or more, still more preferably 15 μm or more, and particularly preferably 20 μm or more. From the viewpoint that it is easy to relieve stress when folding or bending, and it is easy to make a flexible image display device using the transparent adhesive sheet thinner, the thickness of the transparent adhesive sheet according to the embodiment is preferably 100 μm or less, more preferably 80 μm or less, still more preferably 70 μm or less, and particularly preferably 60 μm or less. The above-described lower limit and upper limit of the thickness of the transparent adhesive sheet can be arbitrarily combined.

The total light transmittance of the transparent adhesive sheet according to the embodiment is preferably 85% or more, more preferably 88% or more, and still more preferably 90% or more.

The total light transmittance can be measured, for example, in accordance with JIS-K-7361-1 (ISO13468-1).

The haze of the transparent adhesive sheet according to the embodiment is preferably 1.0% or less, more preferably 0.8% or less, and still more preferably 0.5% or less.

The haze value can be measured, for example, in accordance with JIS-K-7136 (ISO14782).

### (Manufacturing Method of Transparent Adhesive Sheet)

A manufacturing method of the transparent adhesive sheet according to the embodiment is not particularly limited. For example, the transparent adhesive sheet according to the embodiment can be obtained by mixing predetermined amounts of the (meth)acrylic polymer (A), compound (B), and the photopolymerization initiator (C), and as necessary, the photocurable compound (D), the silane coupling agent (E), the additive, and the like to prepare the adhesive agent composition (I), and molding the adhesive agent composition (I) into a sheet shape. As necessary, the transparent adhesive sheet after the molding may be temporary cured.

Examples of a method of mixing each component include a method using a single-screw extruder, a twin-screw extruder, a planetary mixer, a twin-screw mixer, or a pressure kneader.

Examples of a method of molding the adhesive agent composition (I) into a sheet shape include a wet lamination method, a dry lamination method, a cast extrusion method using a T-die, an extrusion lamination method, a calendering or inflation method, an injection molding method, and a liquid injection curing method.

The transparent adhesive sheet according to the embodiment may be formed by dissolving the adhesive agent composition in an appropriate solvent and coating using various coating methods.

The transparent adhesive sheet according to the embodiment described above has high sensitivity to active energy rays that can be cured with high efficiency.

The transparent adhesive sheet according to the embodiment can be suitably used for a flexible image display device. That is, the transparent adhesive sheet according to the embodiment can be suitably used as a transparent adhesive sheet for a member constituting a flexible image display device.

### [Release Film-Provided Transparent Adhesive Sheet]

Another embodiment of the present invention relates to a release film-provided transparent adhesive sheet.

In the transparent adhesive sheet according to the embodiment, it is preferable that a release film be laminated on at least one surface of the transparent adhesive sheet before bonding, and it is more preferable that release films be laminated on both surfaces thereof. An aspect in which a plurality of transparent adhesive sheets are laminated with a release film interposed therebetween may be used.

Examples of the release film include a polyester film, a polyolefin film, a polycarbonate film, a polystyrene film, an acrylic film, a triacetyl cellulose film, and a fluororesin film. Among the above, a polyester film or a polyolefin film is preferable, and a polyester film is more preferable.

In addition, since it is easy to peel off from the transparent adhesive sheet after being irradiated with active energy ray, the release film is preferably a film in which a peeling force measured with a transparent adhesive sheet irradiated with active energy ray having a wavelength of 365 nm with an integrated light amount of 500 to 5,000 mJ/cm² is 0.1 N/cm or less in conditions of a peeling angle of 1800 and a peeling speed of 300 mm/min.

From the viewpoint of processability and handleability, the thickness of the release film is preferably 25 μm or more and 500 μm or less, more preferably 38 μm or more and 250 μm or less, and still more preferably 50 μm or more and 200 μm or less. The above-described lower limit and upper limit of the thickness of the release film can be arbitrarily combined.

### [Laminate for Image Display Device]

Another embodiment of the present invention relates to a laminate for an image display device.

In the laminate for an image display device according to the embodiment, two members constituting the image display device are laminated through the transparent adhesive sheet according to the embodiment of the present invention, in which at least one of the members constituting the image display device has a step with a height difference of 2 μm or more on a contact surface with the transparent adhesive sheet.

Since the transparent adhesive sheet according to the embodiment of the present invention has excellent unevenness followability, the transparent adhesive sheet is deformed by following the step on the surface of the member constituting the image display device, and two members constituting the image display device can be bonded together while absorbing the step.

The member constituting the image display device is not particularly limited, and examples thereof include a cover lens, a polarizing plate, a phase difference film, a barrier film, a touch sensor film, a light-emitting element, PSA, a color filter, a flexible printed circuit board, a metal substrate, and a hard plate.

A material of the member constituting the image display device is not particularly limited. Examples thereof include resin sheets having, as a main component, a resin such as a urethane resin, a cycloolefin resin, a triacetyl cellulose resin, a (meth)acrylate resin, an epoxy resin, and a polyimide resin; thin film glass; and metals. “Main component” herein means a component having the highest mass ratio among components constituting the member constituting the image display device, and the mass ratio is preferably 50% by mass or more, more preferably 55% by mass or more, and still more preferably 60% by mass or more.

The step of the member constituting the image display device on the contact surface with the transparent adhesive sheet is not particularly limited, and examples thereof include various unevenness caused by wiring, printing, pattern development, surface treatment, embossing processing, and the like.

A height difference of the step of the member constituting the image display device is preferably 2 μm or more, more preferably 3 μm or more, and still more preferably 4 μm or more, and is preferably 10 μm or less, more preferably 8 μm or less, still more preferably 7 μm or less, and particularly preferably 6 μm or less. The above-described lower limit and upper limit of the height difference of the step can be arbitrarily combined.

The step of the member constituting the image display device on the contact surface with the transparent adhesive sheet may be, for example, unevenness provided with a height difference of 2 to 10 μm and an interval of 10 mm or less.

From the viewpoint of favorable handleability, the thickness of the laminate for an image display device according to the embodiment is preferably 0.02 mm or more, more preferably 0.03 mm or more, and still more preferably 0.05 mm or more. From the viewpoint of thinning the laminate, the thickness of the laminate for an image display device according to the embodiment is preferably 1.0 mm or less, more preferably 0.7 mm or less, and still more preferably 0.5 mm or less. The above-described lower limit and upper limit of the thickness of the laminate for an image display device can be arbitrarily combined.

A manufacturing method of the laminate for an image display device according to the embodiment is not particularly limited.

For example, a method in which the transparent adhesive sheet according to the embodiment of the present invention is bonded to one member constituting the image display device on a surface having a step, the transparent adhesive sheet is irradiated with active energy ray, the other member constituting the image display device is bonded to the transparent adhesive sheet on the other surface, and the transparent adhesive sheet is hot-melt as necessary by subjecting the transparent adhesive sheet to a heating treatment is an exemplary example. The transparent adhesive sheet according to the embodiment of the present invention can be hot-melt even after curing by active energy ray, and can be bonded so that it follows the step and absorbs the step.

When using the release film-provided transparent adhesive sheet, in which release films are laminated on both surfaces of the transparent adhesive sheet, a transparent adhesive sheet in which one release film has been peeled off is bonded to the member constituting the image display device on a surface having a step, and the transparent adhesive sheet is irradiated with active energy ray through the other release film. Thereafter, the other release film is peeled off, the other member constituting the image display device is bonded to the transparent adhesive sheet on the other surface, and the transparent adhesive sheet is hot-melt as necessary by subjecting the transparent adhesive sheet to a heating treatment.

After irradiating the transparent adhesive sheet with active energy ray to cure, the transparent adhesive sheet may be bonded to each of two members constituting the image display device.

When at least one of two members constituting the image display device transmits light, a method in which the two members constituting the image display device, which have a step on at least one adhesive surface, are laminated through the transparent adhesive sheet according to the embodiment of the present invention, and then the transparent adhesive sheet is irradiated with active energy ray through the member constituting the image display device, which transmits light, may be adopted.

Examples of the active energy ray to be radiated include ionizing radiation such as α-rays, β-rays, γ-rays, neutron beams, and electron beams, ultraviolet rays, and visible light. Among the above, from the viewpoint of suppressing damage to the member constituting the image display device and controlling the reaction, ultraviolet rays are preferable.

Examples of a light source for radiating the active energy ray include a high-pressure mercury lamp, a low-pressure mercury lamp, a metal halide lamp, a xenon lamp, a halogen lamp, an LED lamp, and a fluorescent lamp.

From the viewpoint of curing the transparent adhesive sheet with high efficiency, an irradiation amount of the active energy ray is preferably 5,000 mJ/cm² or less, more preferably 4,500 mJ/cm² or less, and still more preferably 4,200 mJ/cm² or less. From the viewpoint of sufficient curing, the irradiation amount of the active energy ray is preferably 500 mJ/cm² or more, more preferably 1,000 mJ/cm² or more, still more preferably 1,300 mJ/cm² or more, particularly preferably 1,500 mJ/cm² or more, and especially preferably 2,000 mJ/cm² or more. The above-described lower limit and upper limit of the irradiation amount of active energy ray can be arbitrarily combined.

A method of bonding the transparent adhesive sheet on the surface of the member constituting the image display device, having a step, is not particularly limited, and for example, a known method such as roll bonding, press bonding using a parallel plate, and diaphragm bonding can be used. A bonding environment may be either an air bonding method of carrying out bonding at normal pressure or a vacuum bonding method of carrying out bonding under reduced pressure.

In addition, a heating treatment may be performed when the member constituting the image display device and the transparent adhesive sheet are bonded to each other. A heating temperature during the heating treatment is preferably 40° C. or higher and 100° C. or lower, more preferably 50° C. or higher and 90° C. or lower, and still more preferably 55° C. or higher and 85° C. or lower.

A pressing pressure may be applied to the laminate together with the heating treatment. In addition, the heating treatment may be performed together with an autoclave treatment.

### [Flexible Image Display Device]

Still another embodiment of the present invention relates to a flexible image display device.

“Flexible image display device” means an image display device that does not leave any bending marks even after repeated bending, folding, or rolling up operations, and when released from the bent, folded, or rolled up state, quickly recovers to the state before the operation and displays images without distortion.

The flexible image display device according to the embodiment includes the laminate for an image display device according to the embodiment of the present invention. In the flexible image display device according to the embodiment, for example, the laminate for an image display device is disposed on a side of an image display panel opposite to the viewer side, that is, on a light source side.

In the flexible image display device according to the embodiment, other members may be further laminated between the image display panel and the laminate for an image display device according to the embodiment of the present invention or on a side of the laminate for an image display device according to the embodiment of the present invention opposite to the image display panel. Examples of the other members include the same members constituting the image display device as those mentioned in the description of the laminate for an image display device according to the embodiment.

In the flexible image display device according to the embodiment, even when the member constituting the image display device on the contact surface with the adhesive sheet has a step with, for example, a height difference of 2 μm or more, the adhesive sheet follows and absorbs the step, suppressing the generation of bubbles, and also suppresses delamination or cracking even when bent, folded, or rolled up in a low-temperature environment.

The present invention is not limited to the embodiments described above. Within a range not departing from the gist of the present invention, it is possible to appropriately substitute the constituent elements in the above-described embodiments with known constituent elements, and the above-described modification examples may be appropriately combined.

### EXAMPLES

A more detailed description of the present invention will be given below using Examples and Comparative Examples. However, the present invention is not limited to these examples in any way. “part” in Examples means “part by mass”.

Measurements and evaluations in Examples were carried out by the methods shown below.

### (Molecular Weight of Macromonomer)

A 0.2% by mass tetrahydrofuran solution of a macromonomer was prepared, and the weight-average molecular weight (Mw) in terms of standard polystyrene was determined under the following conditions.
GPC device: “HLC-8320” manufactured by Tosoh Corporation
Column: the following columns manufactured by Tosoh Corporation were connected in series and used; as a guard column, “TSK guard column Super HZ-L” (4.6 mmID×2.0 cmL) manufactured by Tosoh Corporation was used;
two “TSKgel Super HZM-M” (4.6 mmID×15 cmL) and one “TSKgel Super HZ2000” (4.6 mmID×15 cmL)
Injection volume: 10 μL
Eluent: tetrahydrofuran (stabilizer: BHT)
Flow rate: 0.35 mL/min
Column temperature: 40° C.

### (Molecular Weight of (Meth)Acrylic Polymer)

A 0.27% by mass tetrahydrofuran solution of a (meth)acrylic copolymer was prepared, and the weight-average molecular weight (Mw) in terms of standard polystyrene was determined under the following conditions.
GPC device: “HLC-8320” manufactured by Tosoh Corporation
Column: two columns “TSKgel Super HZM-H” (6.0 mmID×15 cmL) manufactured by TOSOH Corporation were connected in series and used; as a guard column, “TSK guard column Super HZ-H” (4.6 mmID×3.5 cmL) manufactured by Tosoh Corporation was used.
Injection volume: 10 μL
Eluent: tetrahydrofuran (stabilizer: BHT)
Flow rate: 0.5 mL/min
Column temperature: 40° C.

### (Non-Volatile Content)

Approximately 1 g of a sample was placed on an aluminum dish, dried in an oven equipped with a blower at 105° C. for 2 hours, the mass before and after drying was measured on an electronic balance, and the concentration of the non-volatile content was obtained according to the following expression.

$$Concentration of non - volatile content ( \% ) = ( Mass of sample after drying ( g ) / Mass of sample before drying ( g ) ) \times 100$$

### (Glass Transition Temperature)

An operation in which a release film on one side was removed from a release film-provided transparent adhesive sheet, and the transparent adhesive sheets were laminated using a hand roller was repeated to adjust the thickness thereof to approximately 0.8 mm, and the laminate was punched out into a circular shape with a diameter of 8 mm to obtain a sample. The obtained sample was placed in a rheometer (“DHR-2” manufactured by TA Instruments), and a dynamic viscoelasticity measurement was performed under the conditions of a measurement jig of 8 mm-diameter parallel plate, a frequency of 1 Hz, a measurement temperature of −50° C. to 150° C., and a temperature rising rate of 5° C./min. The glass transition temperature (Tg) defined by the maximal value of Tan δ, which was obtained by a dynamic viscoelasticity measurement in a shear mode at a frequency of 1 Hz, was calculated.

### (Storage Shear Modulus G′)

An operation in which a release film on one side was removed from a release film-provided transparent adhesive sheet produced in each example, and the transparent adhesive sheets were laminated using a hand roller was repeated to adjust the thickness thereof to approximately 0.8 mm, and the laminate was punched out into a circular shape with a diameter of 8 mm to obtain a sample. The obtained sample was placed in a rheometer (“DHR-2” manufactured by TA Instruments), a dynamic viscoelasticity measurement was performed under the conditions of a measurement jig of 8 mm-diameter parallel plate, a frequency of 1 Hz, a measurement temperature of −50° C. to 150° C., and a temperature rising rate of 5° C./min, and a value of storage shear modulus G′ at −20° C., 25° C., 30° C., 60° C., and 80° C. was read.

### (Creep Strain)

An operation in which a release film on one side was removed from a release film-provided transparent adhesive sheet produced in each example, and the transparent adhesive sheets were laminated using a hand roller was repeated to adjust the thickness thereof to 0.8 mm, and the laminate was punched out into a circular shape with a diameter of 8 mm to obtain a sample. The obtained sample was installed in a rheometer (“DHR-2” manufactured by TA Instruments), and a strain after applying a pressure of 2 kPa at 60° C. for 600 seconds was read as a creep strain.

### (Restoration Rate)

An operation in which a release film on one side was removed from a release film-provided transparent adhesive sheet produced in each example, and the transparent adhesive sheets were laminated using a hand roller was repeated to adjust the thickness thereof to 0.8 mm, and the laminate was punched out into a circular shape with a diameter of 8 mm to obtain a sample. The obtained sample was placed in a rheometer (“DHR-2” manufactured by TA Instruments), and the restoration rate was measured under the following measurement conditions.

The restoration rate was calculated by the following expression with a creep strain (γₘₐₓ) after applying a pressure of 2 kPa at 60° C. for 600 seconds and a residual strain (γₘᵢₙ) after 600 seconds from unloading the stress.

$$Restoration rate ( \% ) = [ ( {γ}_{ma x} - {γ}_{m i n} ) / {γ}_{m ax} ] \times 100$$

### (Gel Fraction)

Each release film was removed from the laminate of the release film-provided transparent adhesive sheet and used as a sample.

The sample was wrapped in an SUS wire mesh of 150 mesh, and immersed in ethyl acetate for 24 hours. Thereafter, the adhesive sheet was dried at 70° C. for 4.5 hours, the mass of the adhesive before and after the immersion in ethyl acetate was measured, and the difference between the masses was defined as the mass of the adhesive remaining in the wire mesh in an insoluble state. The percentage of the mass of the insoluble adhesive remaining in the wire mesh (mass after immersion) with respect to the mass of the adhesive before immersion in ethyl acetate (mass before immersion) was calculated as the gel fraction (%) in the fully cured state.

### (Holding Power)

A polyester film for backing was attached to one surface of the transparent adhesive sheet produced in each example, and the transparent adhesive sheet was cut into strips with a width of 20 mm and a length of 100 mm to obtain a test piece. One end portion of the above-described test piece was adhered to an SUS plate such that an adhesive area was 20 mm×20 mm. After curing for 15 minutes in an atmosphere of 70° C., a weight of 500 gf (4.9 N) was provided at the other end portion of the above-described test piece. The SUS plate was allowed to stand vertically such that the weight side was on the lower side, and after a load was applied to the test piece for 30 minutes, a distance (deviation amount) (mm) at which the test piece deviated was measured. In the table, the test piece which fell within 30 minutes is described as “Falling”.

### (Used Material)

SLMA: mixture of an alkyl methacrylate having an alkyl group having 12 carbon atoms and an alkyl methacrylate having an alkyl group having 13 carbon atoms, manufactured by Mitsubishi Chemical Corporation; trade name: Acrylic Ester SL
nBA: n-butyl acrylate (manufactured by Mitsubishi Chemical Corporation)
AMBN: 2,2′-azobis(2-methylbutyronitrile) (manufactured by Otsuka Chemical Co., Ltd.)

### <Compound (B)>

B-1: 4-acryloyloxybenzophenone
B-2: 4-methacryloyloxybenzophenone

### <Photopolymerization Initiator (C)>

C-1: mixture of 4-methylbenzophenone and 2,4,6-trimethylbenzophenone (manufactured by IGM Resins, Esacure TZT)
C-2: 2,2-dimethoxy-2-phenylacetophenone (manufactured by IGM Resins, Inc., Omnirad 651)

### <Photocurable Compound (D)>

D-1: SHIKOH UV-3700B (manufactured by Mitsubishi Chemical Corporation)

### Production Example 1: Production of Macromonomer

100 parts of SLMA, 0.00075 parts of bis[(difluoroboryl)diphenylglyoxymate]cobalt(II) as a chain transfer agent, and 58 parts of ethyl acetate were charged into a four-necked flask equipped with a stirrer, a thermometer, a cooling tube, and a nitrogen gas inlet, and oxygen was replaced with nitrogen bubbling. Next, 0.4 parts of AMBN as a polymerization initiator and 2 parts of ethyl acetate were added thereto. Next, the external temperature was raised to 90° C. in a water bath, and the reaction was carried out in a reflux state for 2 hours. Next, 0.2 parts of AMBN and 20 parts of ethyl acetate were added dropwise thereto over 1 hour, and the reflux state was further maintained for 2 hours. Thereafter, the reaction solution was cooled to 40° C. to obtain a solution containing a macromonomer (SLMA-MM). By adding ethyl acetate to the solution, the concentration of non-volatile content was adjusted to 50% by mass.

The weight-average molecular weight of the macromonomer (SLMA-MM) was 9,420.

### Example 1

### <Production of Polymer>

25 parts of ethyl acetate as a charged solvent, 2 parts of isopropyl alcohol (IPA), and 15 parts of the macromonomer (SLMA-MM) solution (concentration: 50% by mass) were charged into a four-necked flask equipped with a stirrer, a thermometer, a cooling tube, and a nitrogen gas inlet, and the external temperature was raised to 85° C. in a water bath under nitrogen gas ventilation. After the reflux state had stabilized, a mixture consisting of 20 parts of ethyl acetate, 85 parts of nBA, and 0.13 parts of NYPER BK40 MT (manufactured by NOF CORPORATION) was added dropwise thereto over 4 hours. After finishing the dropwise addition and retaining for 1 hour, a mixture consisting of 0.3 parts of PEROCTA O (manufactured by NOF CORPORATION) and 15 parts of ethyl acetate was added thereto over 1 hour. After retaining for 2 hours, 0.5 parts of “IRGANOX 1010” (trade name, manufactured by BASF) as an antioxidant, and 23 parts of ethyl acetate were added thereto, and the mixture was cooled to room temperature to obtain a (meth)acrylic polymer (A-1) (SLMA-MM/nBA (mass ratio)=15/85, weight-average molecular weight: 460,000, Tg: −38° C.).

### <Production of Transparent Adhesive Sheet>

100 parts (solid content) of the above-described (meth)acrylic polymer (A-1), 0.3 parts of compound (β-1), 1.2 parts of the photopolymerization initiator (C-1), 1.5 parts of the photocurable compound (D-1), and 154.5 parts of ethyl acetate were blended to prepare an adhesive agent composition containing a solvent. The above-described adhesive agent composition was developed in a sheet shape on a release film (PET film manufactured by Mitsubishi Chemical Corporation) having a thickness of 100 μm, which had been subjected to a silicone release treatment, such that the thickness after drying was 50 μm.

Next, the sheet-like adhesive agent composition together with the release film was put into a dryer heated to 90° C. and held for 10 minutes to volatilize the solvent contained in the adhesive agent composition. Furthermore, a silicone release-treated release film (PET film manufactured by Mitsubishi Chemical Corporation) having a thickness of 75 μm was laminated on the sheet-like adhesive agent composition from which the solvent had been dried, and using a high-pressure mercury lamp, the adhesive agent composition was cured by ultraviolet irradiation through the release film with an irradiation amount such that the integrated light amount at a wavelength of 365 nm was 4,000 mJ/cm², thereby obtaining a release film-provided transparent adhesive sheet in which the release film was laminated on both sides of a transparent adhesive sheet having a thickness of 50 μm.

### Examples 2 to 10 and Comparative Examples 1 and 2

A release film-provided transparent adhesive sheet was produced in the same manner as in Example 1, except that the blending amount was changed as shown in Table 1.

### Example 11

### <Production of Transparent Adhesive Sheet>

100 parts (solid content) of a (meth)acrylic polymer (A-2) (random copolymer of 2EHA/BA/EMA/HEA (mass ratio)=60/15/5/20; weight-average molecular weight: 770,000, Tg: −23° C.), 0.75 parts of compound (β-1), 0.75 parts of the photopolymerization initiator (C-1), and 152.3 parts of ethyl acetate were blended to prepare an adhesive agent composition containing a solvent. The above-described adhesive agent composition was developed in a sheet shape on a release film (PET film manufactured by Mitsubishi Chemical Corporation) having a thickness of 100 μm, which had been subjected to a silicone release treatment, such that the thickness after drying was 50 μm.

Next, the sheet-like adhesive agent composition together with the release film was put into a dryer heated to 90° C. and held for 10 minutes to volatilize the solvent contained in the adhesive agent composition. Furthermore, a silicone release-treated release film (PET film manufactured by Mitsubishi Chemical Corporation) having a thickness of 75 μm was laminated on the sheet-like adhesive agent composition from which the solvent had been dried, and using a high-pressure mercury lamp, the adhesive agent composition was cured by ultraviolet irradiation through the release film with an irradiation amount such that the integrated light amount at a wavelength of 365 nm was 1,000 mJ/cm², thereby obtaining a release film-provided transparent adhesive sheet in which the release film was laminated on both sides of a transparent adhesive sheet having a thickness of 50 μm.

### Example 12

A release film-provided transparent adhesive sheet was produced in the same manner as in Example 11, except that the blending amount was changed as shown in Table 1.

Table 1 shows the results of measurement and evaluation of the transparent adhesive sheet of each example.

TABLE 1

| | | | | | | | | | | | | | | | | Comparative | |
|---|---|---|---|---|---|---|---|---|---|---|---|---|---|---|---|---|---|
| | | | | Example | | | | | | | | | | | | Example | |
| | | | | 1 | 2 | 3 | 4 | 5 | 6 | 7 | 8 | 9 | 10 | 11 | 12 | 1 | 2 |
| Adhesive | (Meth)acrylic polymer | A-1 | Part | 100 | 100 | 100 | 100 | 100 | 100 | 100 | 100 | 100 | 100 | — | — | 100 | 100 |
| agent | (A) | A-2 | Part | — | — | — | — | — | — | — | — | — | — | 100 | 100 | — | — |
| composition | Compound (B) | B-1 | Part | 0.3 | 0.75 | 1.2 | 0.75 | 1.2 | 1.35 | — | — | — | — | — | — | — | — |
| (I) | | B-2 | Part | — | — | — | — | — | — | 0.3 | 0.75 | 1.2 | 1.2 | 0.75 | 1.2 | — | 1.5 |
| | Photopolymerization | C-1 | Part | 1.2 | 0.75 | 0.3 | — | — | — | 1.2 | 0.75 | 0.3 | — | 0.75 | — | 1.5 | — |
| | initiator (C) | C-2 | Part | — | — | — | 0.75 | 0.3 | 0.15 | — | — | — | 0.3 | — | 0.3 | — | — |
| | Photocurable | D-1 | Part | 1.5 | 1.5 | 1.5 | 1.5 | 1.5 | 1.5 | 1.5 | 1.5 | 1.5 | 1.5 | — | — | 1.5 | 1.5 |
| | compound (D) | | | | | | | | | | | | | | | | |
| | Mass ratio (B/C) | | — | 0.25 | 1 | 4 | 1 | 4 | 9 | 0.25 | 1 | 4 | 4 | 1 | 4 | — | — |
| Transparent | Glass transition temperature (Tg) | | ° C. | −38 | −38 | −38 | −39 | −37 | −38 | −38 | −38 | −39 | −37 | −29 | −28 | −38 | −40 |
| adhesive | Storage shear modulus | −20° C. | kPa | 283 | 294 | 303 | 264 | 319 | 313 | 294 | 286 | 237 | 319 | 625 | 782 | 260 | 237 |
| sheet | (G′) | 25° C. | kPa | 45 | 53 | 47 | 47 | 56 | 53 | 42 | 41 | 38 | 44 | 59 | 64 | 35 | 30 |
| | | 30° C. | kPa | 40 | 48 | 43 | 43 | 52 | 49 | 37 | 36 | 34 | 39 | 54 | 57 | 31 | 25 |
| | | 60° C. | kPa | 25 | 35 | 28 | 29 | 38 | 35 | 20 | 20 | 19 | 23 | 29 | 31 | 16 | 9 |
| | | 80° C. | kPa | 21 | 31 | 24 | 24 | 34 | 30 | 15 | 15 | 14 | 18 | 20 | 21 | 10 | 3 |

| | | | | | | | | | | | | | | | |
|---|---|---|---|---|---|---|---|---|---|---|---|---|---|---|---|
| G′(-20° C.)/G′(60° C.) | — | 11.3 | 8.4 | 10.8 | 9.1 | 8.4 | 8.9 | 14.7 | 14.3 | 12.5 | 13.9 | 21.5 | 25.2 | 16.3 | 26.3 |
| Creep strain | % | 19 | 10 | 15 | 15 | 9 | 11 | 51 | 49 | 61 | 34 | 106 | 87 | 228 | 4102 |
| Restoration rate (60° C.) | % | 94 | 94 | 93 | 95 | 96 | 96 | 89 | 88 | 89 | 91 | 73 | 76 | 71 | 5 |
| Holding power | mm | <0.2 | <0.2 | <0.2 | <0.2 | <0.2 | <0.2 | <0.2 | <0.2 | <0.2 | <0.2 | 1 | 0.5 | 0.5 | Falling |
| Gel fraction | % | 73 | 80 | 75 | 75 | 81 | 78 | 61 | 60 | 61 | 65 | 47 | 51 | 44 | 0 |

As shown in Table 1, in the transparent adhesive sheets of Examples 1 to 12, in which compound (B) and the photopolymerization initiator (C) were used in combination, the gel fraction was higher and the curing reaction proceeded with high efficiency, as compared with the transparent adhesive sheets of Comparative Examples 1 and 2, in which only one of compound (B) or the photopolymerization initiator (C) was used.

1. A transparent adhesive sheet comprising a cured product of an adhesive agent composition (I),
wherein the adhesive agent composition (I) contains a precursor containing: a (meth)acrylic polymer (A); a compound (B) having, in a molecule, a radically polymerizable functional group having a carbon-carbon double bond, and a structure which generates a radical; and a photopolymerization initiator (C) consisting of a compound other than compound (B), and
a storage shear modulus (G′(−20° C.)) at −20° C. obtained by a dynamic viscoelasticity measurement in a shear mode at a frequency of 1 Hz, is 10 kPa or more and 1,000 kPa or less.

2. The transparent adhesive sheet according to claim 1,
wherein a ratio ((G′(−20° C.)/G′(60° C.)) of the storage shear modulus G′(−20° C.) at −20° C. to a storage shear modulus G′(60° C.) at 60° C. obtained by the dynamic viscoelasticity measurement in the shear mode at the frequency of 1 Hz, is 20 or less.

3. The transparent adhesive sheet according to claim 1,
wherein a storage shear modulus (G′(30° C.)) at 30° C. obtained by the dynamic viscoelasticity measurement in the shear mode at the frequency of 1 Hz, is 100 kPa or less.

4. The transparent adhesive sheet according to claim 1,
wherein compound (B) comprises an ethylenically unsaturated group-containing benzophenone-based compound.

5. The transparent adhesive sheet according to claim 1,
wherein compound (B) has at least one structure selected from the group consisting of a benzophenone structure, a benzil structure, an o-benzoyl benzoic acid ester structure, a thioxanthone structure, a 3-ketocoumarin structure, a 2-ethyl anthraquinone structure, and a camphorquinone structure.

6. The transparent adhesive sheet according to claim 1,
wherein the photopolymerization initiator (C) includes a hydrogen abstraction-type photoinitiator (C1).

7. The transparent adhesive sheet according to claim 1,
wherein the photopolymerization initiator (C) includes a cleavage-type photoinitiator (C2).

8. The transparent adhesive sheet according to claim 1,
wherein the glass transition temperature (Tg) defined by the maximal value of Tan δ obtained by the dynamic viscoelasticity measurement in the shear mode at the frequency of 1 Hz, is −20° C. or lower.

9. The transparent adhesive sheet according to claim 1,
wherein the contained amount of compound (B) is 0.01 parts by mass or more and 10 parts by mass or less with respect to 100 parts by mass of the (meth)acrylic polymer (A).

10. The transparent adhesive sheet according to claim 1,
wherein the mass ratio (B/C) of the contained amount of compound (B) to the contained amount of the photopolymerization initiator (C) is 0.2 to 10.

11. The transparent adhesive sheet according to claim 1,
wherein the adhesive agent composition (I) contains a photocurable compound (D).

12. The transparent adhesive sheet according to claim 1,
wherein the contained amount of a monofunctional urethane (meth)acrylate in the adhesive agent composition (I) is 10% by mass or less.

13. The transparent adhesive sheet according to claim 1,
wherein the adhesive agent composition (I) contains a silane coupling agent (E).

14. The transparent adhesive sheet according to claim 1,
wherein the (meth)acrylic polymer (A) is a block copolymer or a graft copolymer having a segment including a constituent unit derived from an alkyl (meth)acrylate having an alkyl group having 9 or more and 30 or less carbon atoms.

15. The transparent adhesive sheet according to claim 1,
wherein, when the thickness of the transparent adhesive sheet is set to 0.7 to 1.0 mm, a restoration rate calculated from the following expression, expressed with a strain (γₘₐₓ) when a pressure of 2 kPa is applied for 600 seconds at a temperature of 60° C. and the strain (γₘᵢₙ) after 600 seconds from unloading the stress, is 75% or more,
$$restoration rate ( \% ) = [ ( {γ}_{m ax} - {γ}_{m i n} ) / {γ}_{m ax} ] \times 100 .$$

16. The transparent adhesive sheet according to claim 1,
wherein the gel fraction is 45% or more.

17. A release film-provided transparent adhesive sheet, comprising:
the transparent adhesive sheet according to claim 1; and
a release film laminated with the transparent adhesive sheet.

18. A transparent adhesive sheet for a member constituting a flexible image display device, comprising:
the transparent adhesive sheet according to claim 1.

19. A laminate for an image display device, comprising:
two members constituting an image display device; and
the transparent adhesive sheet according to claim 1,
wherein the two members are laminated through the transparent adhesive sheet, and
at least one of the members constituting the image display device has a step with a height difference of 2 μm or more on a contact surface with the transparent adhesive sheet.

20. A flexible image display device, comprising:
the laminate for an image display device according to claim 19.
